(19) United States
(12) Patent Application Publication
(10) Pub. No.: US 2025/0393141 A1
(43) Pub. Date: Dec. 25, 2025

(54) BAFFLE AND CABINET HAVING THE BAFFLE

(71) Applicant: Fulian Precision Electronics (Tianjin) Co., LTD., Tianjin (CN)

(72) Inventor: TI-AN TSAI, New Taipei (TW)

(21) Appl. No.: 18/963,635

(22) Filed: Nov. 28, 2024

(30) Foreign Application Priority Data
Jun. 21, 2024 (CN) 202410810381.3

(51) Int. Cl. H05K 5/02; H05K 7/14

(52) U.S. Cl. CPC H05K 5/0214; H05K 7/1488

(57) ABSTRACT

A baffle and a cabinet having the baffle are disclosed. The baffle includes a main body, a first member, and an elastic member, and the cabinet includes a mounting member. The baffle can retain the mounting member between the first member and the elastic member through the rebounding force of the elastic member after being compressed by the mounting member, without being limited to the form of connecting holes defined at the mounting member. Therefore, the baffle can be installed on any form of mounting member, and can be installed and disassembled by pressing the elastic member of the baffle, thereby improving installation and disassembly efficiency.

### FIELD

The subject matter herein generally relates to servers, and more particularly, to a baffle and a cabinet having the baffle.

### BACKGROUND

Servers may be located within cabinets. Baffles may be set inside the cabinets to block hot air or cold air from the servers, thereby protecting the servers in the cabinets. However, the installation and disassembly processes of the baffles are complicated, and different cabinets may require different shapes of fixing holes for connecting the baffles, resulting in poor compatibility of the cabinets with the baffles.

Therefore, there is room for improvement in the art.

### BRIEF DESCRIPTION OF THE DRAWINGS

Implementations of the present disclosure will now be described, by way of embodiments only, with reference to the attached figures.

FIG. 1 is a diagram of an embodiment of a baffle according to the present disclosure.

FIG. 2 is a diagram showing the baffle of FIG. 1 from another angle.

FIG. 3 is a diagram showing a partial structure of the baffle of FIG. 1.

FIG. 4 is a diagram showing a partial structure of the baffle of FIG. 1 from another angle.

FIG. 5 is a diagram of the baffle of FIG. 1 from yet another angle.

FIG. 6 is a diagram showing the baffle of FIG. 1 installed onto a mounting member.

FIG. 7 is a diagram of an embodiment of a cabinet according to the present disclosure.

FIG. 8 is a diagram showing a partial structure of the cabinet of FIG. 7 from another angle.

### DETAILED DESCRIPTION

Unless otherwise defined, all technical and scientific terms used herein have the same meaning as commonly understood by persons skill in the art. The terms used herein are only for the purpose of describing specific embodiments, and not intended to limit the embodiments of the present disclosure.

It should be noted that when a component is referred to as being “fixed on” or “mounted on” another component, it may be directly on the other component or there may also be an intervening component. When a component is considered to be “set on” another component, it may be in direct contact with the other component or there may also be an intervening component.

It is understood that the term “perpendicular” is used to describe an ideal relationship between two components. In practical manufacturing or usage, an approximate or exact perpendicular relationship may exist between the two components. For instance, “perpendicular” may refer to an angle between two lines ranging from 90°±10°, an angle between two planes ranging from 90°±10° (as a dihedral angle), or an angle between a line and a plane ranging from 90°±10°. The two components described as “perpendicular” may not be absolutely straight lines or planes, they may be approximately straight or planar, and it suffices for the purpose of this description that they macroscopically extend in a straight-line or planar direction to be considered as “straight lines” or “planes”.

Unless otherwise defined, the term “plurality” as used herein to describe the quantity of components specifically refers to two or more of such components.

Some embodiments of the present disclosure will be described in detail below with reference to the drawings. The following embodiments and features of the embodiments may be combined with each other in the absence of conflict.

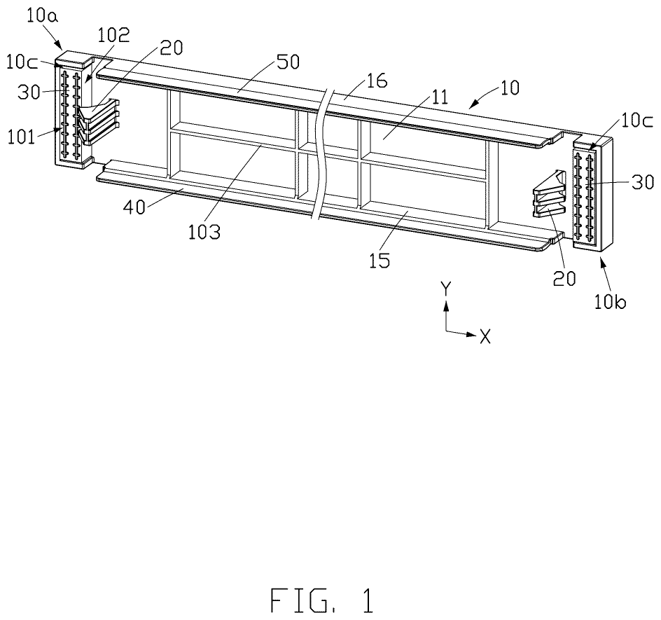

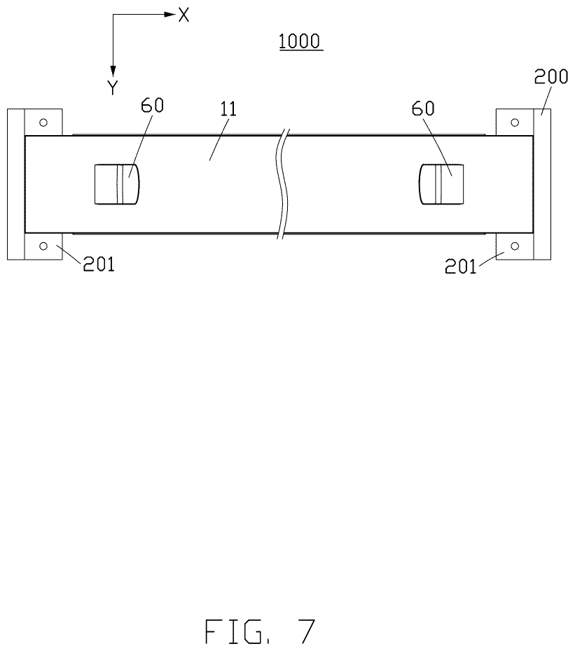

Referring to FIGS. 1 and 7, an embodiment of the present disclosure provides a baffle 100 configured for installing in a cabinet 1000, and the cabinet 1000 includes a mounting member 201. The baffle 100 includes a main body 10, a first member 20, and an elastic member 30. The main body 10 includes a first end 10a and a second end 10b arranged along a first direction X. At least one of the first end 10a and the second end 10b defines a receiving cavity 10c. The elastic member 30 is disposed within the receiving cavity 10c, and the first member 20 is connected to the main body 10. The elastic member 30 protrudes from the receiving cavity 10c and can be compressed by the mounting member 201. Thus, the elastic member 30 may rebound to retain the mounting member 201 between the first member 20 and the elastic member 30.

The baffle 100 of the present disclosure retains the mounting member 201 between the first member 20 and the elastic member 30 through the rebounding force of the elastic member 30 after being compressed by the mounting member 201. Thus, the installation and disassembly processes of the baffle 100 is not limited to the shape of connecting holes defined at the mounting member 201. Therefore, the baffle 100 can be installed onto any mounting member 201, and can be installed and disassembled by pressing the elastic member 30 of the baffle 100, thereby simplifying the installation and disassembly processes of the baffle 100 and improving installation and disassembly efficiency.

As shown in FIG. 1, in some embodiments, the first end 10a defines the receiving cavity 10c, and the second end 10b also defines the receiving cavity 10c. The receiving cavities 10c of the first end 10a and the second end 10b are both provided with the elastic member 30.

In other embodiments, the first end 10a defines the receiving cavity 10c, and the second end 10b is provided with a magnetic member (not shown) that can adhere to the mounting member 201.

In other embodiments, the second end 10b defines the receiving cavity 10c, and the first end 10a is provided with the magnetic member (not shown) that can adhere to the mounting member 201.

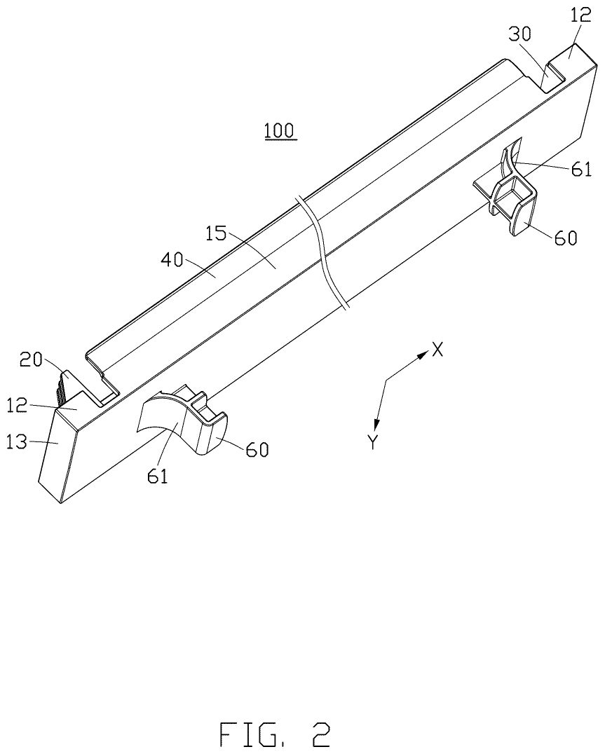

Referring to FIGS. 1 to 3, in some embodiments, the main body 10 includes a bottom wall 11, a first connecting wall 12, a second connecting wall 13, and a third connecting wall 14. The first member 20 is fixed to the bottom wall 11, and the first connecting wall 12, the second connecting wall 13, and the third connecting wall 14 are all connected to the bottom wall 11. The first connecting wall 12, the second connecting wall 13, and the third connecting wall 14 enclose to form the receiving cavity 10c. The first connecting wall 12 and the third connecting wall 14 are opposite to each other along a second direction Y, which is perpendicular to the first direction X. The second connecting wall 13 is connected to the first connecting wall 12 and the third connecting wall 14, and forms a first opening 101 and a second opening 102. The elastic member 30 protrudes from the first opening 101, and the second opening 102 faces the first member 20. The second opening 102 facilitates the assembly and disassembly of the elastic member 30. The second opening 102, when being arranged to face the first member 20, is conducive to limiting the position of the elastic member 30, thereby reducing the possibility of the elastic member 30 detaching from the receiving cavity 10c through the second opening 102.

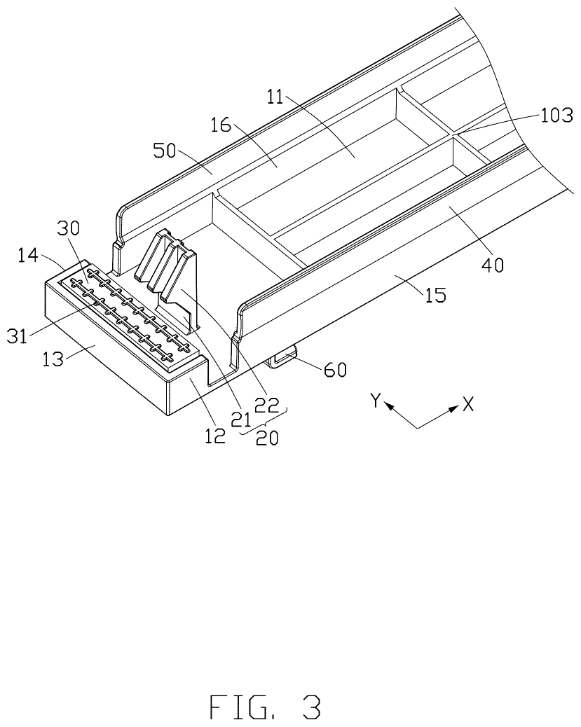

As shown in FIG. 3, in some embodiments, the main body 10 further includes a first side wall 15 and a second side wall 16, both of which are connected to the bottom wall 11. The first side wall 15 and the second side wall 16 are opposite to each other along the second direction Y. The first connecting wall 12 and the first side wall 15 are spaced apart from each other along the first direction X, and the second connecting wall 14 and the second side wall 16 are spaced apart from each other along the first direction X.

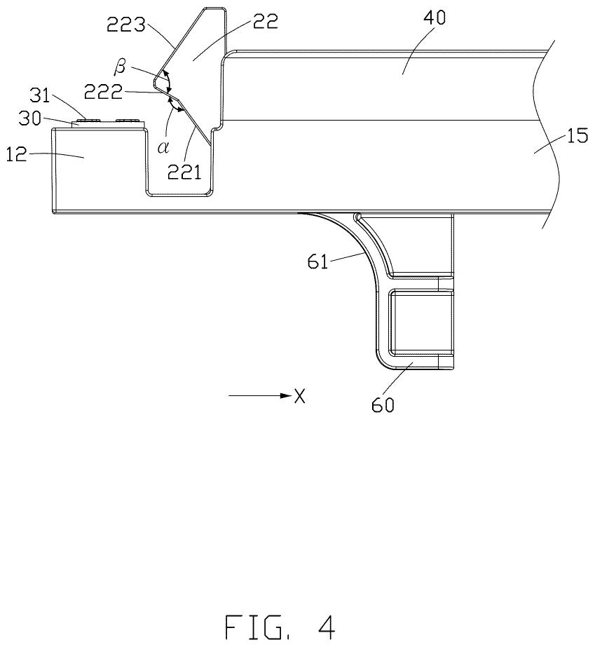

Referring to FIGS. 3 and 4, in some embodiments, the baffle 100 further includes a first extending wall 40 connected to a side of the first side wall 15 facing away from the bottom wall 11. The first extending wall 40 protrudes from the first side wall 15 in a direction opposite to the second direction Y.

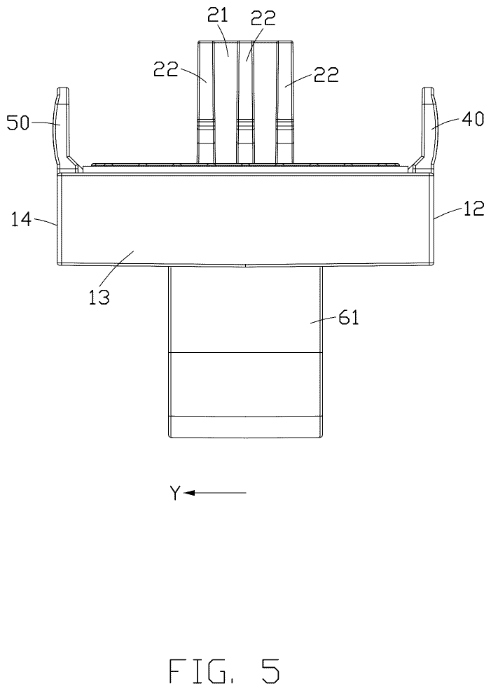

Referring to FIGS. 3 and 5, in some embodiments, the baffle 100 further includes a second extending wall 50 connected to a side of the second side wall 16 facing away from the bottom wall 11. The second extending wall 50 protrudes from the second side wall 16 along the second direction Y.

Furthermore, the first extending wall 40 is an arcuate wall, and the second extending wall 50 is also an arcuate wall, which facilitates the installation of the baffle 100.

When multiple baffles 100 are installed to a server, the first extending wall 40 of one baffle 100 comes into contact with the second extending wall 50 of an adjacent baffle 100. As such, the gaps between adjacent baffles 100 are reduced, and dust, hot and cold air, etc., are prevented from entering the cabinet 1000, thereby protecting the equipment (such as servers) within the cabinet 1000.

As shown in FIGS. 1 and 3, in some embodiments, the baffle 100 further includes a reinforcing portion 103 connected to the bottom wall 11, the first side wall 15, and the second side wall 16. The reinforcing portion 103 can strengthen the structural strength of the main body 10 and reduce the deformation of the baffle 100.

Referring to FIGS. 3 to 5, in some embodiments, the first member 20 includes a connecting portion 21 and a retaining portion 22. The connecting portion 21 is fixed to the bottom wall 11, and the retaining portion 22 is fixed to the connecting portion 21. The retaining portion 22 may include a first wall 221 and a second wall 222 connected to the first wall 221, and the first wall 221 is fixed to the connecting portion 21. The first wall 221 and the second wall 222 form a first angle α configured to retain the mounting member 201.

Furthermore, 150°≤α≤165°, which not only facilitates the installation of the baffle 100 on the mounting member 201 and improves the stability of the baffle 100 on the mounting member 201, but is also conducive to the retain of the mounting member 201 between the first member 20 and the elastic member 30.

Furthermore, α may be, but not limited to any one of 150°, 151°, 152°, 153°, 154°, 155°, 156°, 157°, 158°, 159°, 160°, 161°, 162°, 163°, 164°, and 165°.

In some embodiments, a recess is disposed at the junction of the first wall 221 and the second wall 222. The recess is configured to retain the mounting member 201, thereby enhancing the stability of the baffle 100 on the mounting member 201.

In other embodiments, a protuberance is disposed at the junction of the first wall 221 and the second wall 222. The protuberance is configured to retain the mounting member 201, thereby enhancing the stability of the baffle 100 on the mounting member 201.

Referring to FIG. 4, in some embodiments, the retaining portion 22 further includes a third wall 223 connected to the second wall 222. The third wall 223 and the second wall 222 form a second angle β, and the second angle β is an obtuse angle. Therefore, the obstruction of the third wall 223 to the mounting member 201 can be reduced, such that the baffle 100 is easily installed on the mounting member 201.

Referring to FIGS. 3 and 5, in some embodiments, the first member 20 includes multiple retaining portions 22 spaced apart from each other along the second direction Y. The multiple retaining portions 22 cooperatively retain the mounting member 201, such that the stability of the baffle 100 on the mounting member 201 can be further enhanced.

Referring to FIGS. 1 and 3, in some embodiments, the elastic member 30 is provided with at least one protrusion 31. The protrusion 31 may be resisted against the mounting member 201, which increases the friction between the elastic member 30 and the mounting member 201, thereby further enhancing the stability of the baffle 100 on the mounting member 201 and reducing the likelihood of the baffle 100 separating off the mounting member 201. Optionally, the elastic member 30 may be a foam member.

Furthermore, the elastic member 30 is provided with multiple protrusions 31 arranged along the first direction X. Optionally, each of the protrusions 31 may be arranged in a cross shape.

Furthermore, multiple elastic members 30 are arranged in the receiving cavity 10c along the second direction Y. The baffle 100 is installed onto the mounting member 201 through multiple elastic members 30, which can reduce the risk of the baffle plate 100 separating off from the mounting member 201 due to elastic fatigue of a single elastic member 30.

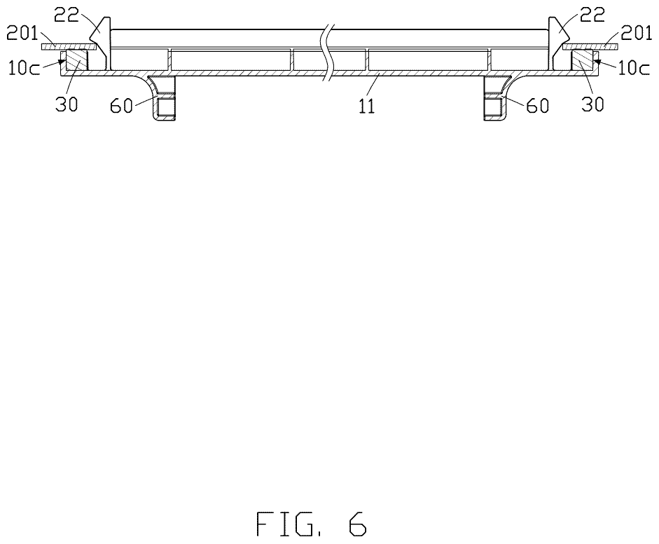

Referring to FIGS. 6 to 8, in some embodiments, the baffle 100 further includes a second member 60 connected to a side of the bottom wall 11 facing away from the first member 20. The second member 60 is disposed near the elastic member 30, such that the elastic member 30 is compressed by the second member 60.

Furthermore, the second member 60 includes a fourth connecting wall 61. The fourth connecting wall 61 arcuately extends towards the elastic member 30, which is conducive to the transmission of the pressing force to the elastic member 30. When the baffle 100 is installed to the mounting member 201, the fourth connecting wall 61 facilitates the rapid compression of the elastic member 30, thereby facilitating the installation of baffle 100 to the mounting member 201.

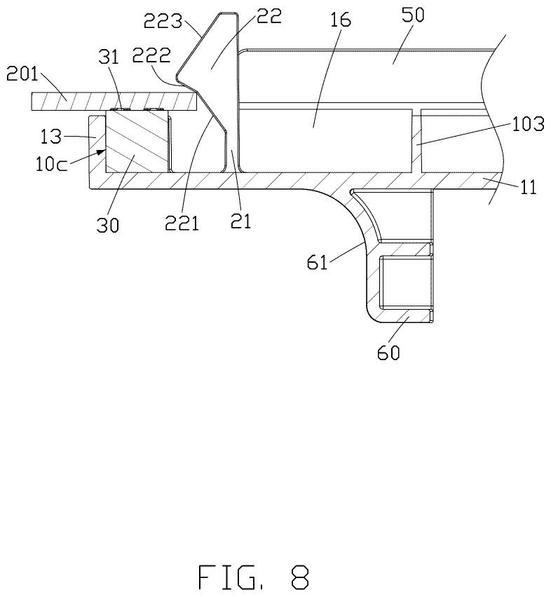

Referring to FIGS. 7 and 8, an embodiment of the present disclosure also provides a cabinet 1000. The cabinet 1000 includes a cabinet body 200 and the baffle 100 according to any one of the aforementioned embodiments. The cabinet body 200 includes two mounting members 201 arranged opposite to each other, and the baffle 100 is installed on the two mounting members 201.

In some embodiments, the cabinet 1000 includes multiple baffles 100. The first extending wall 40 of one baffle 100 is connected to the second extending wall 50 of an adjacent baffle 100. Thus, the gaps between adjacent baffles 100 are reduced, and dust, hot and cold air, etc., are prevented from entering the cabinet 1000, thereby protecting the equipment (such as servers) within the cabinet 1000.

The above descriptions are some specific embodiments of the present disclosure, but the actual application process cannot be limited only to these embodiments. For those of ordinary skill in the art, other modifications and changes made according to the technical concept of the present disclosure should all belong to the protection scope of the present disclosure.

What is claimed is:

1. A baffle configured for installing in a cabinet comprising a mounting member, the baffle comprising:
a main body comprising a first end and a second end opposite to each other along a first direction, at least one of the first end and the second end defining a receiving cavity;
a first member connected to the main body; and
an elastic member arranged in the receiving cavity, wherein the elastic member protrudes from the receiving cavity and is configured to be compressed by the mounting member, and the elastic member is further configured to rebound to retain the mounting member between the first member and the elastic member.

2. The baffle of claim 1, wherein the main body comprises a bottom wall, a first connecting wall, a second connecting wall, and a third connecting wall, each of the first connecting wall, the second connecting wall, and the third connecting wall is connected to the bottom wall, and the first connecting wall, the second connecting wall, and the third connecting wall cooperatively define the receiving cavity;
the second connecting wall is connected to the first connecting wall and the third connecting wall, and the first connecting wall, the second connecting wall, and the third connecting wall cooperatively define a first opening and a second opening;
the elastic member protrudes from the first opening, and the second opening faces the first member.

3. The baffle of claim 2, wherein the main body further comprises a first side wall and a second side wall, each of the first side wall and the second side wall is connected to the bottom wall, and the first side wall and the second side wall are opposite to each other along a second direction perpendicular to the first direction.

4. The baffle of claim 3, further comprising a first extending wall and a second extending wall, wherein the first extending wall is connected to the first side wall, and the second extending wall is connected to the second side wall.

5. The baffle of claim 4, wherein the first extending wall protrudes from the first side wall in a direction from the second side wall to the first side wall.

6. The baffle of claim 4, wherein the second extending wall protrudes from the second side wall in a direction from the first side wall to the second side wall.

7. The baffle of claim 3, further comprising a reinforcing portion connected to the bottom wall, the first side wall, and the second side wall.

8. The baffle of claim 1, wherein the first member comprises a connecting portion and a retaining portion fixed to the connecting portion, the connecting portion is fixed to the main body;
the retaining portion comprises a first wall and a second wall connected to the first wall, the first wall is fixed to the connecting portion, and the first wall and the second wall cooperatively define a first angle α, and the first angle is configured to retain the mounting member between the first member and the elastic member.

9. The baffle of claim 8, wherein 150°≤α≤165°.

10. The baffle of claim 8, wherein the first member comprises a plurality of retaining portions, each adjacent two of the plurality of retaining portions are spaced from each other along a second direction perpendicular to the first direction.

11. The baffle of claim 8, wherein the retaining portion further comprises a third wall connected to the second wall, the third wall and the second wall cooperatively define a second angle, and the second angle is an obtuse angle.

12. The baffle of claim 1, wherein the elastic member comprises a protrusion configured to resist against the mounting member.

13. The baffle of claim 1, wherein the elastic member is a foam member.

14. The baffle of claim 1, further comprising a second member connected to a side of the main body facing away from the first member, the second member comprises a fourth connecting wall, and the fourth connecting wall arcuately extends towards the elastic member.

15. A cabinet, comprising:
a cabinet body comprising two mounting members opposite to each other; and
a baffle connected to the two mounting members, the baffle comprising:
a main body comprising a first end and a second end opposite to each other along a first direction, at least one of the first end and the second end defining a receiving cavity;
a first member connected to the main body; and
an elastic member arranged in the receiving cavity, wherein the elastic member protrudes from the receiving cavity and is configured to be compressed by the two mounting members, and the elastic member is further configured to rebound to retain the mounting members between the first member and the elastic member.

16. The cabinet of claim 15, wherein the main body comprises a bottom wall, a first connecting wall, a second connecting wall, and a third connecting wall, each of the first connecting wall, the second connecting wall, and the third connecting wall is connected to the bottom wall, and the first connecting wall, the second connecting wall, and the third connecting wall cooperatively define the receiving cavity;
the second connecting wall is connected to the first connecting wall and the third connecting wall, and the first connecting wall, the second connecting wall, and the third connecting wall cooperatively defines a first opening and a second opening;
the elastic member protrudes from the first opening, and the second opening faces the first member.

17. The cabinet of claim 16, wherein the main body further comprises a first side wall and a second side wall, each of the first side wall and the second side wall is connected to the bottom wall, and the first side wall and the second side wall are opposite to each other along a second direction perpendicular to the first direction.

18. The cabinet of claim 17, wherein the baffle further comprises a first extending wall and a second extending wall, the first extending wall is connected to the first side wall, and the second extending wall is connected to the second side wall.

19. The cabinet of claim 18, wherein the first extending wall protrudes from the first side wall in a direction from the second side wall to the first side wall.

20. The cabinet of claim 18, wherein the second extending wall protrudes from the second side wall in a direction from the first side wall to the second side wall.
